(19) United States
(12) Patent Application Publication
(10) Pub. No.: US 2014/0088898 A1
(43) Pub. Date: Mar. 27, 2014

(54) Method for Estimation State of Health for ESS

(71) Applicant: SK INNOVATION CO., LTD., Seoul (KR)

(72) Inventor: Jae Hwan Lim, Daejeon (KR)

(73) Assignee: SK Innovation Co., Ltd., Seoul (KR)

(21) Appl. No.: 14/122,958

(22) PCT Filed: May 30, 2012
(86) PCT No.: PCT/KR2012/004231

§ 371 Date: Nov. 27, 2013

(30) Foreign Application Priority Data
Jun. 2, 2011 (KR) 10-2011-0053293

(51) Int. Cl. G01R 31/36

(52) U.S. Cl. CPC G01R 31/362
USPC 702/63

(57) ABSTRACT

Provided is a system for estimating a state of health for an ESS, including: a pack voltage calculating processor receiving cell voltage of a battery cell that is the most basic of an energy storage system (ESS) to calculate pack voltage of a battery pack; an SOH estimating processor receiving the pack voltage from the pack voltage calculating processor and setting preconditions for estimating state of health (SOH) to estimate the SOH meeting the preconditions; an SOH calculating processor confirming pack voltage when meeting the preconditions at the time of estimating the SOH and calculating the SOH by using a voltage difference between the confirmed current pack voltage and initial pack voltage; and an SOC compensating processor calculating a state of charge (SOC) compensating capacity by multiplying initial rated capacity by the SOH received from the SOH calculating processor.

### TECHNICAL FIELD

The present invention relates to a system and a method for estimating a state of health of an ESS, and more particularly, to a technology of estimating a state of health for an ESS and compensating for battery capacity therethrough.

### BACKGROUND ART

A battery has been developed from a battery for IT devices to an ESS that stores electricity from photovoltaic power generation or wind power generation and uses the stored power, if necessary. Currently, a battery has been in the limelight as facilities or energy storage systems for stably supplying power generated from portable power supply and new renewable energy sources to a power grid. In addition, in a secondary battery market that has been interested as new energy sources, an interest in an ESS field has been increased.

The ESS is an apparatus that stores power supplied from a power plant and transfers the stored power to required places at a time when power is required. The ESS is a storage unit storing power and using the stored power at required place and time and has been recently become a hot topic due to eco-friendly characteristics.

The new renewable energy such as the recently spotlighted wind power generation, photovoltaic power generation, and the like, has decreased power generation stability and therefore, needs to have improved stability by being coupled with the ESS in the future.

The ESS, which is a large-capacity power storage apparatus using an LIB or a lead storage battery, is an apparatus that stores overproducing power and discharges power when power is lack to stabilize a supply and demand of power. The ESS is an apparatus that stores surplus power when a power demand is small and uses the stored power at a peak time when the power demand is large or at a time when the electric rate is expensive to increase power use efficiency.

When using the ESS, new power generation facility investment cost can be reduced and energy generation and use efficiency can be maximized due to connection with the new renewable energy sources. In these conditions, a technology needs to be developed for estimating a state of health for the ESS is needed. The present invention relates to estimation of a state of health for the ESS and compensation of battery capacity.

As a search result, in a method of estimating a state of health used in a battery management system that manages a battery in which a plurality of battery cells are formed in a single pack in Korean Patent No. 10-0740113 (hereinafter, referred to as Prior Patent 1 entitled “Method of estimating state of health and battery management system using the same”), the method includes: a) measuring first pack voltage and first pack current of a battery; b) measuring second pack voltage and second pack current of a battery after a first period; c) calculating pack internal resistance based on the first pack voltage, the first pack current, the second pack voltage, and the second pack current and calculating peak output of a battery using the calculated pack internal resistance, d) outputting a first signal when the calculated peak output is smaller than first reference peak output, and e) outputting a second signal when the peak output is larger than the first reference peak output and is smaller than second reference peak output that is larger than the first reference peak output, wherein the first signal is a signal informing that defects of a battery are present due to the deterioration of the battery and the second signal is a warning signal informing that the battery is deteriorated.

In addition, in Korean Patent 10-0889179 (hereinafter, referred to as Prior Patent 2 entitled “Apparatus for controlling of inverter circuit for estimating state of health and inverter circuit thereof”), the apparatus includes: an information receiver connected with a battery and an inverter and receiving battery information and inverter information, a cell control module controlling each cell voltage of a battery, and a voltage frequency control module controlling voltage and frequency of an inverter; and a main controller forcibly discharging or bypassing specific cells for a predetermined time by controlling the cell control module if it is determined that voltage of the specific cells is not the same as other cells from the battery information, controlling output voltage and frequency of the inverter by controlling the voltage frequency control module according to the inverter information, and calculating a state of health by increasing currently charging and discharging frequency if it is determined that accumulated capacity obtained by accumulating consumption capacity of a battery is larger than or equal to rated capacity of a battery by using the battery information, wherein the main controller calculates internal impedance by dividing a difference between a primary voltage value and a secondary voltage value by consumption current when the difference between the primary voltage value and the secondary voltage value is larger than 0 and compensates for state of health according to the calculated internal impedance.

*However, the present invention relates to state of health based on a battery voltage variation pattern that maps and estimates battery capacity corresponding to the corresponding battery voltage variation pattern from a lookup table in which a correlation between the battery voltage variation pattern and the battery capacity is represented and battery capacity is defined for each battery voltage variation pattern and is different from Prior Patent 1 and Prior Patent 2 in that the development thereof cannot be easily derived.

### CITATION LIST

### Patent Documents

Korean Patent No. 0740113 (Registration Date : Jul. 10, 2007)

Korean Patent No. 0889179 (Registration Date : Mar. 6, 2009)

### DISCLOSURE OF INVENTION

### Technical Problem

An object of the present invention is to provide a method for estimating a state of health for ESS, which is a large-capacity power storage apparatus using an LIB or a lead storage battery, capable of storing overproducing power and discharging the stored power when power is lack to stabilize a supply and demand of power.

### Solution to Problem

In one general aspect, there is provided a system for estimating a state of health for an ESS, including: a pack voltage calculating processor receiving cell voltage of a battery cell that is the most basic of an energy storage system (ESS) to calculate pack voltage of a battery pack; an SOH estimating processor receiving the pack voltage from the pack voltage calculating processor and setting preconditions for estimating state of health (SOH) to estimate the SOH meeting the preconditions; an SOH calculating processor confirming pack voltage when meeting the preconditions at the time of estimating the SOH and calculating the SOH by using a voltage difference between the confirmed current pack voltage and initial pack voltage; and an SOC compensating processor calculating a state of charge (SOC) compensating capacity by multiplying initial rated capacity by the SOH received from the SOH calculating processor.

As the preconditions, battery temperature of ESS may be 23° to 27°, current flowing in the ESS may be 0.5 C-rate or more, and the SOC calculated from a controller of the ESS may be 49% to 51%.

The SOH calculating processor may maintain a lookup table in which the voltage difference and the SOH are written corresponding to each other and derive the SOH corresponding to the voltage difference from the lookup table when meeting the preconditions at the time of estimating the SOH.

The SOC compensating processor may calculate the SOC by substituting the SOC compensating capacity into a rated capacity area.

In another general aspect, there is provided a method for estimating a state of health for an ESS, including: receiving pack voltage of a battery pack; estimating SOH meeting preconditions by setting the preconditions for estimating the SOH; confirming the pack voltage when meeting the preconditions at the time of estimating the SOH and calculating a voltage difference between the confirmed current pack voltage and initial pack voltage; calculating the SOH by deriving the SOH corresponding to the voltage difference from a pre-stored lookup table; calculating SOC compensating capacity by multiplying the initial rated capacity by the SOH; and compensating for the SOC by substituting the SOC compensating capacity into a rated capacity area.

### Advantageous Effects of Invention

According to the system and method for estimating a state of health for an ESS of the exemplary embodiments of the present invention, it is possible to make a power management design of an ESS more effective by accurately estimating a state of health.

### BRIEF DESCRIPTION OF DRAWINGS

FIG. 1 is a diagram showing a charging and discharging characteristic curve of a battery.

FIG. 2 is a diagram showing a configuration of a system for estimating a state of health for an ESS.

FIG. 3 is a diagram showing a lookup table.

FIG. 4 is a flow chart of a method for estimating a state of health for an ESS.

### BEST MODE FOR CARRYING OUT THE INVENTION

Hereinafter, a system and a method for estimating a state of health for an ESS of exemplary embodiments of the present invention will be described with reference to the accompanying drawings. The following introduced drawings are provided by way of example so as to fully convey an idea of the present invention to a person skilled in the art to which the present invention pertains. Accordingly, the scope of the present invention is not restricted to the following description and accompanying drawings. In addition, throughout the specification, like reference numerals denotes like components.

Here, unless indicated otherwise, the terms used in the specification including technical and scientific terms have the same meaning as those that are usually understood by those who skilled in the art to which the present invention pertains, and detailed description of the known functions and constitutions that may obscure the gist of the present invention will be omitted.

A battery has been developed from a battery for IT devices to an ESS that stores electricity from photovoltaic power generation or wind power generation and uses the stored power, if necessary. The ESS uses a battery for a high-capacity ESS. Therefore, in the ESS, estimating a state of health is a very important technology. The present invention relates to estimating a state of health for an ESS.

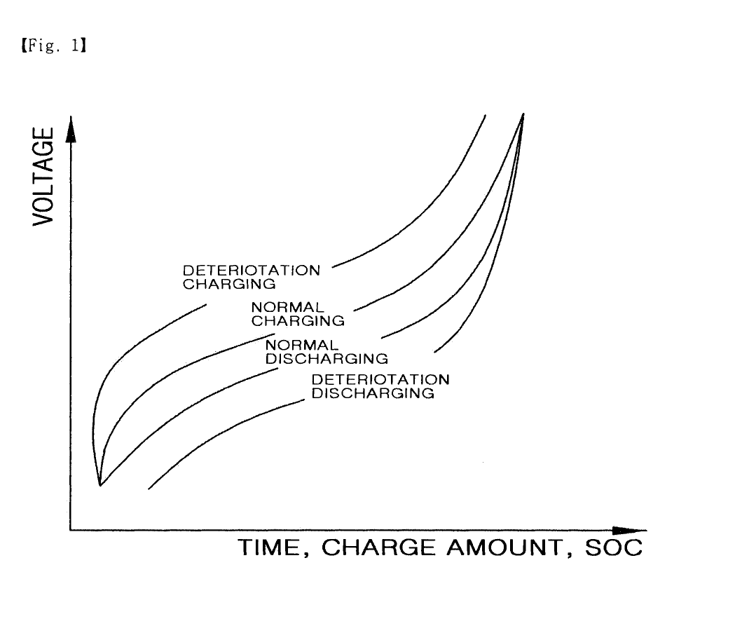

FIG. 1 is a diagram showing a charging and discharging characteristic curve of a battery.

A charging and discharging characteristic curve is generally showing non-linearly as shown in FIG. 1. Since battery internal resistance is increased according to usage of a battery, battery voltage rises more than initial voltage at the time of charging and falls at the time of discharging. Exemplary embodiments of the present invention are used to estimate a reduced amount of battery capacity and compensate for a charged amount of a battery using the same.

A current pattern of the ESS generally continues to charge or discharge a predetermined amount unlike a current pattern used in a car, in particular, a hybrid car or an electric car. Although the ESS is used to adjust a frequency of a power distribution system by making a sustain pattern of charging or discharging fast according to the purpose, the exemplary embodiment of the present invention uses, as a reference, when the current pattern is charged or discharged at a predetermined amount.

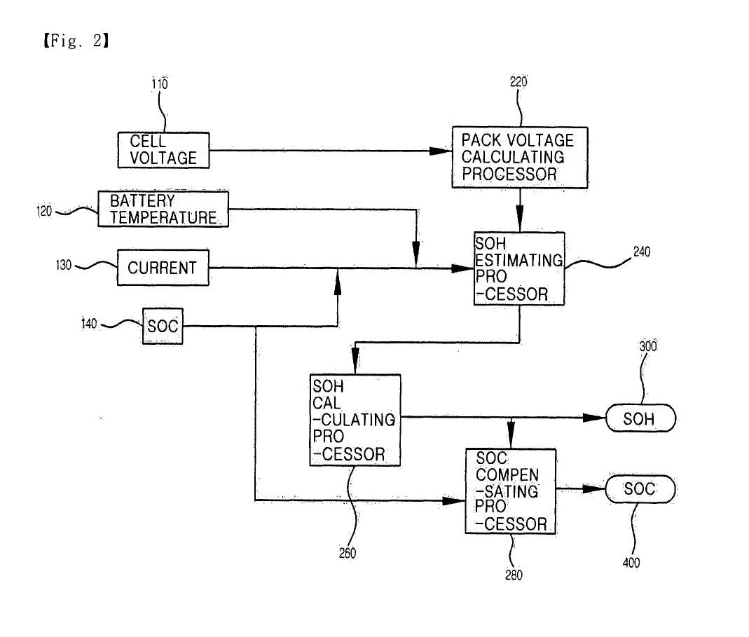

FIG. 2 is a diagram showing a configuration of a system for estimating a state of health for an ESS.

Estimating the state of health for the ESS and compensating for the battery capacity are implemented by processes of a pack voltage calculating processor 220, an SOH estimating processor 240, an SOH calculating processor 260, and an SOC compensating processor 280.

The pack voltage calculating processor 220 calculates by the pack voltage of the battery pack by receiving cell voltage 110 of a battery cell that is the most basic of the ESS. The cell voltage may be several or several tens according to the environment of the ESS. When the pack voltage apparatus capable of measuring pack voltage is included in the ESS, the pack voltage apparatus may also be used, instead of the pack voltage calculating processor 220.

The SOH estimating processor 240 receives the pack voltage from the pack voltage calculating processor 220 as shown in FIG. 2.

The SOH estimating processor 240 estimates the SOH based on battery temperature of the ESS 120, current flowing in the ESS 130, the SOC calculated from a controller of the ESS 140. As described above, the battery temperature of the ESS estimates the SOH in a state in which the battery temperature within the ESS is the most stabilized state and may be implemented as 23° to 27°. Current flowing in the above-mentioned ESS obtained through a current sensor attached to the ESS and needs to be in 0.5 C-rate or more since the pack voltage variation cannot be estimated using a fine current amount. In addition, the SOC calculated from the controller of the above-mentioned ESS may be 49% to 51% under the most stabilized condition for estimating the SOH.

The SOH estimating processor 240 sets preconditions for estimating the SOH as described above to estimate the SOH meeting the preconditions.

When the SOH calculating processor 260 satisfies the preconditions set by the SOH estimating processor 240, it confirms the pack voltage and calculates the voltage difference between the confirmed current pack voltage and the initial pack voltage. Here, the initial pack voltage is obtained by an experimental value based on 4% to 6% of the SOC.

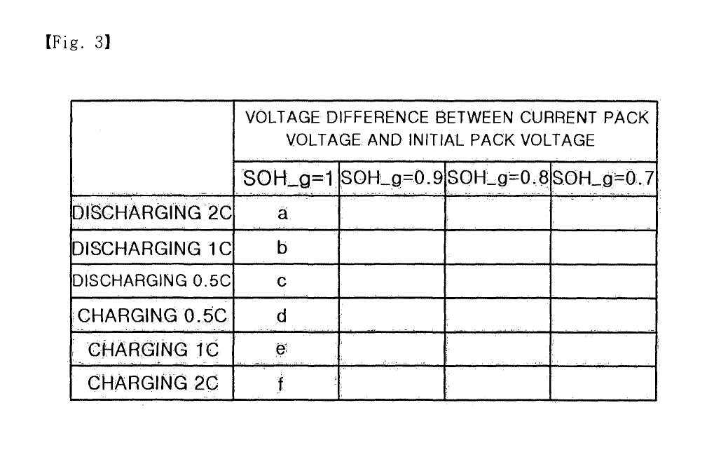

The SOH calculating processor 260 calculates the SOH 300 by using the calculated voltage difference. FIG. 3 is a diagram showing a lookup table. The SOH calculating processor 260 maintains the lookup table in which the voltage difference and the SOH are written corresponding to each other. The lookup table defines the SOH due to the voltage difference and shows values calculated by the experiment.

When meeting the preconditions, the SOH calculating processor 260 derives the SOH corresponding to the voltage difference from the lookup table at the time of estimating the SOH, thereby calculating the SOH. The calculated SOH may be transferred to the controller through communications and the SOC compensating processor 280 may perform the compensation of the SOC using the same.

The SOC compensating processor 280 multiplies initial rated capacity by the SOH received from the SOH calculating processor 260, thereby calculating the SOC compensating capacity 400. The SOH has a value between 0 and 1. The SOC compensating processor 280 substitutes the SOC compensating capacity into the rated capacity area, thereby compensating for the SOC. The compensated SOC may be transferred to the controller by communications.

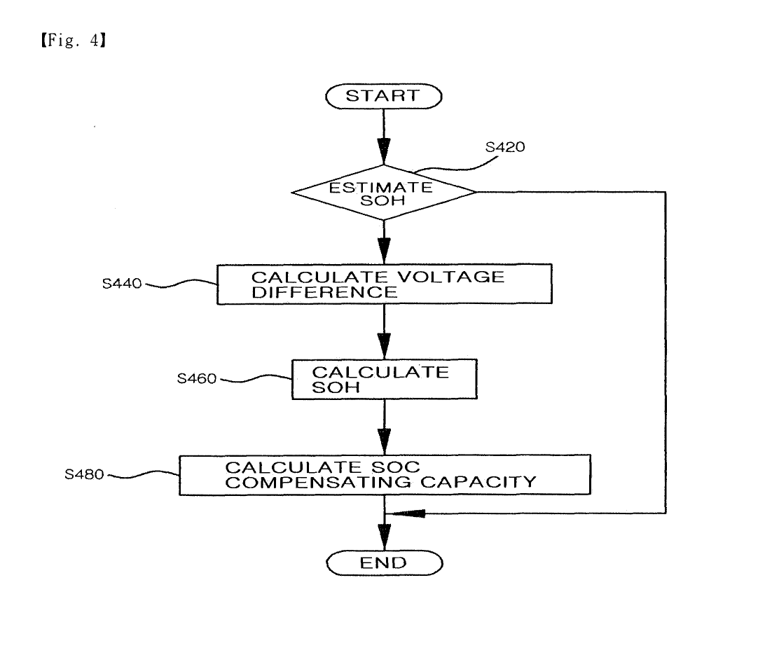

FIG. 4 is a flow chart of a method for estimating a state of health for the ESS.

As shown in FIG. 4, the method for estimating a state of health for the ESS includes: receiving pack voltage of a battery pack (not shown), estimating the SOH meeting preconditions by setting the preconditions for estimating the SOH (S420), confirming the pack voltage when meeting the preconditions at the time of estimating the SOH and calculating the voltage difference between the confirmed current pack voltage and the initial pack voltage (S440), calculating the SOH by deriving the SOH corresponding to the voltage difference from the pre-stored lookup table (S460), calculating the SOC compensating capacity by multiplying the initial rated capacity by the SOH (S480), and compensating for the SOC by substituting the SOC compensating capacity into the rated capacity area (not shown). The description thereof is the same as the processes of the system for estimating a state of health for the ESS as described above and therefore, will be omitted.

As described above, the present invention is described with reference to specific matters such as the detailed components and the limited exemplary embodiments, but is provided to help a general understanding of the present invention. Therefore, the present invention is not limited to the above exemplary embodiments and can be variously changed and modified from the description by a person skilled in the art to which the present invention pertain. Although the present invention is described with reference to the above-mentioned embodiments and drawings, the present invention is not limited to the embodiments.

Accordingly, a person skilled in the art to which the present invention pertains can perform various modifications and changes based on the above description. Therefore, the sprit of the present invention should not be limited to the above-described embodiments, and the following claims as well as all modified equally or equivalently to the claims are intended to fall within the scope and spirit of the invention.

1. A system for estimating a state of health for an ESS, comprising:
a pack voltage calculating processor receiving cell voltage of a battery cell that is the most basic of an energy storage system (ESS) to calculate pack voltage of a battery pack;
*an SOH estimating processor receiving the pack voltage from the pack voltage calculating processor and setting preconditions for estimating state of health (SOH) to estimate the SOH meeting the preconditions;
an SOH calculating processor confirming pack voltage when meeting the preconditions at the time of estimating the SOH and calculating the SOH by using a voltage difference between the confirmed current pack voltage and initial pack voltage; and
an SOC compensating processor calculating a state of charge (SOC) compensating capacity by multiplying initial rated capacity by the SOH received from the SOH calculating processor.

2. The system of claim 1, wherein as the preconditions, battery temperature of ESS is 23° to 27°, current flowing in the ESS is 0.5 C-rate or more, and the SOC calculated from a controller of the ESS is 49% to 51%.

3. The system of claim 1, wherein the SOH calculating processor maintains a lookup table in which the voltage difference and the SOH are written corresponding to each other and derives the SOH corresponding to the voltage difference from the lookup table when meeting the preconditions at the time of estimating the SOH.

4. The system of claim 1, wherein the SOC compensating processor calculates the SOC by substituting the SOC compensating capacity into a rated capacity area.

5. A method for estimating a state of health for an ESS, comprising:
receiving pack voltage of a battery pack;
estimating an SOH meeting preconditions by setting the preconditions for estimating the SOH;
confirming the pack voltage when meeting the preconditions at the time of estimating the SOH and calculating a voltage difference between the confirmed current pack voltage and initial pack voltage;
calculating the SOH by deriving the SOH corresponding to the voltage difference from a pre-stored lookup table;
calculating SOC compensating capacity by multiplying the initial rated capacity by the SOH; and
compensating for the SOC by substituting the SOC compensating capacity into a rated capacity area.
